(19) United States
(12) Patent Application Publication
(10) Pub. No.: US 2023/0325543 A1
(43) Pub. Date: Oct. 12, 2023

(54) COLOR SIMULATION OF ANTI-REFLECTIVE COATINGS ON THREE-DIMENSIONAL (3D) OBJECTS IN A HEAD-MOUNTED DISPLAY (HMD)

(71) Applicant: Meta Platforms Technologies, LLC, Menlo Park, CA (US)

(72) Inventors: Tristan TOM, Hillsborough, CA (US); Weihua GAO, Rancho Santa Margarita, CA (US)

(73) Assignee: Meta Platforms Technologies, LLC, Menlo Park, CA (US)

(21) Appl. No.: 18/112,211

(22) Filed: Feb. 21, 2023

Related U.S. Application Data
(60) Provisional application No. 63/329,581, filed on Apr. 11, 2022.

(51) Int. Cl. G06F 30/10

(52) U.S. Cl. CPC G06F 30/10

(57) ABSTRACT

According to examples, apparatuses, systems, and methods for simulating the color appearance of coatings on three-dimensional objects are described. Geometric data relating to a geometry of an object characterized by a curved surface is received. A substrate representation of a substrate color associated with the object is determined based on the geometric data. A coating representation of a coating applied to the object is determined based on the geometric data and a thin film model of the coating. An appearance of the coating applied to the object is simulated by displaying the coating representation superimposed on the substrate representation.

### PRIORITY

This patent application claims priority to U.S. Provisional Patent Application No. 63/329,581, entitled “Color Simulation of Anti-Reflective Coatings On Three-Dimensional (3d) Objects In A Head-Mounted Display (HMD),” filed on Apr. 11, 2022.

### TECHNICAL FIELD

This patent application relates generally to color simulation, and more specifically, to apparatuses, systems, and methods for simulating the color appearance of coatings on three-dimensional objects in augmented reality (AR), virtual reality (VR), or mixed reality (MR) systems.

### BACKGROUND

With recent advances in technology, prevalence and proliferation of content creation and delivery has increased greatly in recent years. In particular, interactive content such as virtual reality (VR) content, augmented reality (AR) content, mixed reality (MR) content, and content within and associated with a real and/or virtual environment (e.g., a “metaverse”) has become appealing to consumers.

To facilitate delivery of this and other related content, many providers have endeavored to offer various forms of wearable display systems. One such example may be a head-mounted display (HMD) device, such as a wearable eyewear, a wearable headset, or eyeglasses. In some examples, the head-mounted display (HMD) device may project or direct light to form a first image and a second image, and with these images, to generate “binocular” vision for viewing by a user.

Some head-mounted devices are made of plastic material. In some cases, the plastic material may be coated with an anti-reflective (AR) coating to satisfy optical performance criteria and/or improve the appearance of the head-mounted device.

### BRIEF DESCRIPTION OF DRAWINGS

Features of the present disclosure are illustrated by way of example and not limited in the following figures, in which like numerals indicate like elements. One skilled in the art will readily recognize from the following that alternative examples of the structures and methods illustrated in the figures can be employed without departing from the principles described herein.

FIG. 1 illustrates a block diagram of an artificial reality system environment including a near-eye display, according to an example.

FIG. 2 illustrates a perspective view of a near-eye display in the form of a head-mounted display (HMD) device, according to an example.

FIG. 3 illustrates a perspective view of a near-eye display in the form of a pair of glasses, according to an example.

FIG. 4 illustrates a flow diagram illustrating an example method for simulating the color appearance of a coating on a three-dimensional object, according to various examples.

FIG. 5 illustrates a diagram of a set of reflectance curves, according to some examples.

FIG. 6 illustrates an example color chart for an angle of incidence of 0 degrees, according to an example.

FIG. 7 illustrates an example color chart for an angle of incidence of 10 degrees, according to an example.

FIG. 8 illustrates an example color chart for an angle of incidence of 20 degrees, according to an example.

FIG. 9 illustrates an example color chart for an angle of incidence of 30 degrees, according to an example.

FIG. 10 illustrates an example color chart for an angle of incidence of 40 degrees, according to an example.

FIG. 11 illustrates an example color chart for an angle of incidence of 50 degrees, according to an example.

FIG. 12 illustrates a diagram of an anti-reflective coating as viewed from a left-shifted view, a front view, and a right-shifted view.

FIG. 13 illustrates a diagram of a simulation of a coating characterized by an unstable color shift that is dependent on the angle of incidence.

FIG. 14 illustrates a diagram of a simulation of an anti-reflective (AR) coating applied to four different substrates.

FIG. 15 illustrates a block diagram of a computer system for simulating the color appearance of coatings on three-dimensional objects, according to an example.

### DETAILED DESCRIPTION

For simplicity and illustrative purposes, the present application is described by referring mainly to examples thereof. In the following description, numerous specific details are set forth in order to provide a thorough understanding of the present application. It will be readily apparent, however, that the present application may be practiced without limitation to these specific details. In other instances, some methods and structures readily understood by one of ordinary skill in the art have not been described in detail so as not to unnecessarily obscure the present application. As used herein, the terms “a” and “an” are intended to denote at least one of a particular element, the term “includes” means includes but not limited to, the term “including” means including but not limited to, and the term “based on” means based at least in part on. The terms “connected” and “coupled” are not limited to physical or mechanical connections or couplings and can include electrical connections or couplings, whether direct or indirect. The terms “circuit” and “circuitry” and “controller” may include a single component or a plurality of components that are active and/or passive and that are connected or otherwise coupled to provide the described function. The term “operatively coupled” includes wired coupling, wireless coupling, magnetic coupling, radio communication, software-based communication, and/or combinations thereof.

Head-mounted devices (HMDs) and other three-dimensional (3D) objects may have coatings applied to achieve functional objectives and/or to improve their appearance. For example, an anti-reflective film may be applied to reduce the reflection of light from the surface of the head-mounted device. Reflected light from the surface of the head-mounted device may cause visual artifacts in the field of vision of a user, such as glints, halos, and the like. Reflected light may also cause light scattering, which may affect adjacent cameras or sensors. Anti-reflective films may be made of multi-layer stacks that reduce reflection.

Some computer-implemented simulation techniques may predict the color appearance of an anti-reflective film on an object. However, some simulation techniques may not accurately represent colors as they would appear on an actual object. For example, some simulation techniques assume that the object consists of flat surfaces. Because light reflects differently from curved surfaces relative to flat surfaces, such simulation techniques may fail to accurately represent colors on three-dimensional objects having curved surfaces. For example, simulation techniques that assume that objects consist of flat surfaces may fail to consider the effect of varying angles of incidence on reflectance and perceived color.

Disclosed herein are systems, methods, and apparatuses that may simulate the color appearance of coatings on three-dimensional objects. In various examples, a simulation system may receive data, such as point cloud data, that describes the geometry of a head-mounted display (HMD) device or other three-dimensional (3D) object. The simulation system may use the data to determine angles of incidence to the object from a user-specified point of view. The simulation system may simulate the effects of varying angles of incidence of curved surfaces on reflectance of light and perceived color. The color appearance of a coating on a surface with coating uniformity may be simulated, even if the surface is part of a three-dimensional object with a complex form factor, such as a head-mounted device. As head-mounted devices integrate large cosmetic surfaces with optical performance criteria, understanding and controlling color appearance may facilitate reducing development times and implementation costs.

According to various examples, apparatuses, systems, and methods for simulating the color appearance of coatings on three-dimensional objects are described. Geometric data relating to a geometry of an object characterized by a curved surface is received. A substrate representation of a substrate color associated with the object is determined based on the geometric data. A coating representation of a coating applied to the object is determined based on the geometric data and a thin film model of the coating. An appearance of the coating applied to the object is simulated by displaying the coating representation superimposed on the substrate representation.

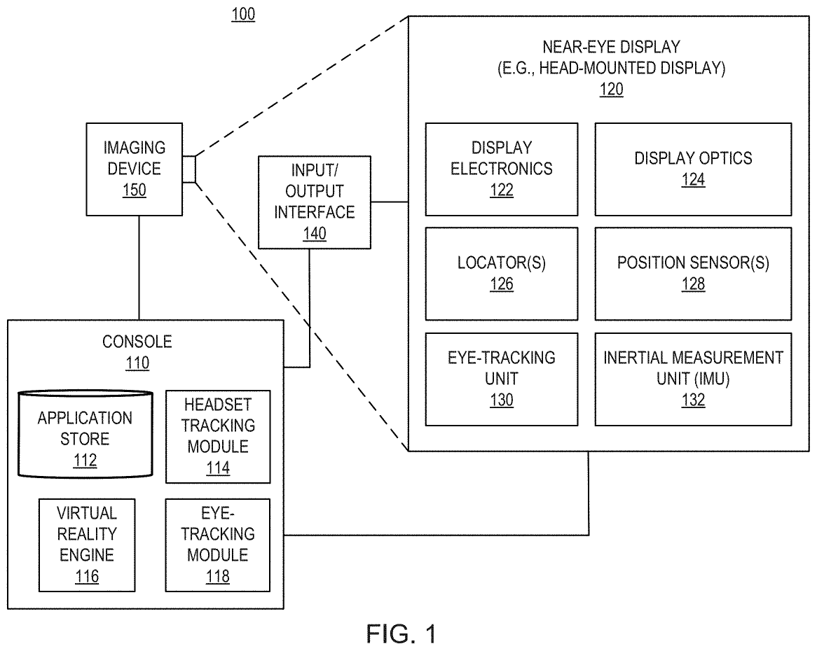

FIG. 1 illustrates a block diagram of an artificial reality system environment 100 including a near-eye display, according to an example. As used herein, a “near-eye display” may refer to a device (e.g., an optical device) that may be in close proximity to a user's eye. As used herein, “artificial reality” may refer to aspects of, among other things, a “metaverse” or an environment of real and virtual elements, and may include use of technologies associated with virtual reality (VR), augmented reality (AR), and/or mixed reality (MR). As used herein a “user” may refer to a user or wearer of a “near-eye display.”

As shown in FIG. 1, the artificial reality system environment 100 may include a near-eye display 120, an optional external imaging device 150, and an optional input/output interface 140, each of which may be coupled to a console 110. The console 110 may be optional in some instances as the functions of the console 110 may be integrated into the near-eye display 120. In some examples, the near-eye display 120 may be a head-mounted display (HMD) that presents content to a user.

In some instances, for a near-eye display system, it may generally be desirable to expand an eyebox, reduce display haze, improve image quality (e.g., resolution and contrast), reduce physical size, increase power efficiency, and increase or expand field of view (FOV). As used herein, “field of view” (FOV) may refer to an angular range of an image as seen by a user, which is typically measured in degrees as observed by one eye (for a monocular HMD) or both eyes (for binocular HMDs). Also, as used herein, an “eyebox” may be a two-dimensional box that may be positioned in front of the user's eye from which a displayed image from an image source may be viewed.

In some examples, in a near-eye display system, light from a surrounding environment may traverse a “see-through” region of a waveguide display (e.g., a transparent substrate) to reach a user's eyes. For example, in a near-eye display system, light of projected images may be coupled into a transparent substrate of a waveguide, propagate within the waveguide, and be coupled or directed out of the waveguide at one or more locations to replicate exit pupils and expand the eyebox.

In some examples, the near-eye display 120 may include one or more rigid bodies, which may be rigidly or non-rigidly coupled to each other. In some examples, a rigid coupling between rigid bodies may cause the coupled rigid bodies to act as a single rigid entity, while in other examples, a non-rigid coupling between rigid bodies may allow the rigid bodies to move relative to each other.

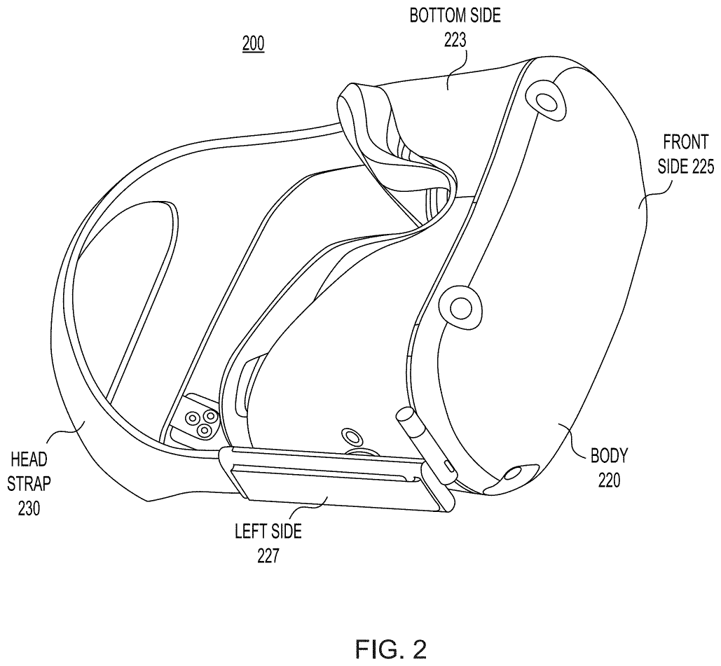

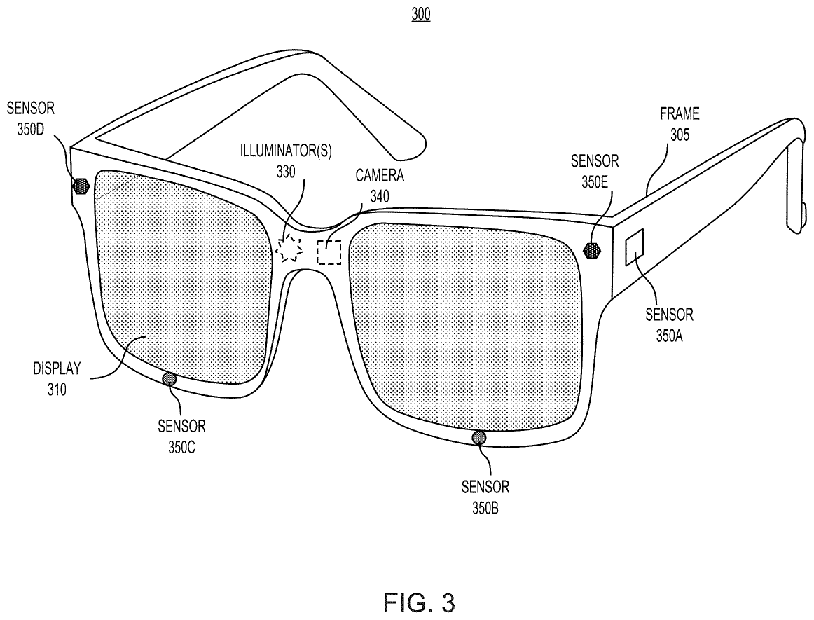

In some examples, the near-eye display 120 may be implemented in any suitable form-factor, including a HMD, a pair of glasses, or other similar wearable eyewear or device. Examples of the near-eye display 120 are further described below with respect to FIGS. 2 and 3. Additionally, in some examples, the functionality described herein may be used in a HMD or headset that may combine images of an environment external to the near-eye display 120 and artificial reality content (e.g., computer-generated images). Therefore, in some examples, the near-eye display 120 may augment images of a physical, real-world environment external to the near-eye display 120 with generated and/or overlaid digital content (e.g., images, video, sound, etc.) to present an augmented reality to a user.

In some examples, the near-eye display 120 may include any number of display electronics 122, display optics 124, and an eye-tracking unit 130. In some examples, the near-eye display 120 may also include one or more locators 126, one or more position sensors 128, and an inertial measurement unit (IMU) 132. In some examples, the near-eye display 120 may omit any of the eye-tracking unit 130, the one or more locators 126, the one or more position sensors 128, and the inertial measurement unit (IMU) 132, or may include additional elements.

In some examples, the display electronics 122 may display or facilitate the display of images to the user according to data received from, for example, the optional console 110. In some examples, the display electronics 122 may include one or more display panels. In some examples, the display electronics 122 may include any number of pixels to emit light of a predominant color such as red, green, blue, white, or yellow. In some examples, the display electronics 122 may display a three-dimensional (3D) image, e.g., using stereoscopic effects produced by two-dimensional panels, to create a subjective perception of image depth.

In some examples, the display optics 124 may display image content optically (e.g., using optical waveguides and/or couplers) or magnify image light received from the display electronics 122, correct optical errors associated with the image light, and/or present the corrected image light to a user of the near-eye display 120. In some examples, the display optics 124 may include a single optical element or any number of combinations of various optical elements as well as mechanical couplings to maintain relative spacing and orientation of the optical elements in the combination. In some examples, one or more optical elements in the display optics 124 may have an optical coating, such as an anti-reflective coating, a reflective coating, a filtering coating, and/or a combination of different optical coatings.

In some examples, the display optics 124 may also be designed to correct one or more types of optical errors, such as two-dimensional optical errors, three-dimensional optical errors, or any combination thereof. Examples of two-dimensional errors may include barrel distortion, pincushion distortion, longitudinal chromatic aberration, and/or transverse chromatic aberration. Examples of three-dimensional errors may include spherical aberration, chromatic aberration field curvature, and astigmatism.

In some examples, the one or more locators 126 may be objects located in specific positions relative to one another and relative to a reference point on the near-eye display 120. In some examples, the optional console 110 may identify the one or more locators 126 in images captured by the optional external imaging device 150 to determine the artificial reality headset's position, orientation, or both. The one or more locators 126 may each be a light-emitting diode (LED), a corner cube reflector, a reflective marker, a type of light source that contrasts with an environment in which the near-eye display 120 operates, or any combination thereof.

In some examples, the external imaging device 150 may include one or more cameras, one or more video cameras, any other device capable of capturing images including the one or more locators 126, or any combination thereof. The optional external imaging device 150 may be to detect light emitted or reflected from the one or more locators 126 in a field of view of the optional external imaging device 150.

In some examples, the one or more position sensors 128 may generate one or more measurement signals in response to motion of the near-eye display 120. Examples of the one or more position sensors 128 may include any number of accelerometers, gyroscopes, magnetometers, and/or other motion-detecting or error-correcting sensors, or any combination thereof.

In some examples, the inertial measurement unit (IMU) 132 may be an electronic device that generates fast calibration data based on measurement signals received from the one or more position sensors 128. The one or more position sensors 128 may be located external to the inertial measurement unit (IMU) 132, internal to the inertial measurement unit (IMU) 132, or any combination thereof. Based on the one or more measurement signals from the one or more position sensors 128, the inertial measurement unit (IMU) 132 may generate fast calibration data indicating an estimated position of the near-eye display 120 that may be relative to an initial position of the near-eye display 120. For example, the inertial measurement unit (IMU) 132 may integrate measurement signals received from accelerometers over time to estimate a velocity vector and integrate the velocity vector over time to determine an estimated position of a reference point on the near-eye display 120. Alternatively, the inertial measurement unit (IMU) 132 may provide the sampled measurement signals to the optional console 110, which may determine the fast calibration data.

The eye-tracking unit 130 may include one or more eye-tracking systems. As used herein, “eye tracking” may refer to determining an eye's position or relative position, including orientation, location, and/or gaze of a user's eye. In some examples, an eye-tracking system may include an imaging system that captures one or more images of an eye and may optionally include a light emitter, which may generate light that is directed to an eye such that light reflected by the eye may be captured by the imaging system. In other examples, the eye-tracking unit 130 may capture reflected radio waves emitted by a miniature radar unit. These data associated with the eye may be used to determine or predict eye position, orientation, movement, location, and/or gaze.

In some examples, the near-eye display 120 may use the orientation of the eye to introduce depth cues (e.g., blur image outside of the user's main line of sight), collect heuristics on the user interaction in the virtual reality (VR) media (e.g., time spent on any particular subject, object, or frame as a function of exposed stimuli), some other functions that are based in part on the orientation of at least one of the user's eyes, or any combination thereof. In some examples, because the orientation may be determined for both eyes of the user, the eye-tracking unit 130 may be able to determine where the user is looking or predict any user patterns, etc.

In some examples, the input/output interface 140 may be a device that allows a user to send action requests to the optional console 110. As used herein, an “action request” may be a request to perform a particular action. For example, an action request may be to start or to end an application or to perform a particular action within the application. The input/output interface 140 may include one or more input devices. Example input devices may include a keyboard, a mouse, a game controller, a glove, a button, a touch screen, or any other suitable device for receiving action requests and communicating the received action requests to the optional console 110. In some examples, an action request received by the input/output interface 140 may be communicated to the optional console 110, which may perform an action corresponding to the requested action.

In some examples, the optional console 110 may provide content to the near-eye display 120 for presentation to the user in accordance with information received from one or more of external imaging device 150, the near-eye display 120, and the input/output interface 140. For example, in the example shown in FIG. 1, the optional console 110 may include an application store 112, a headset tracking module 114, a virtual reality engine 116, and an eye-tracking module 118. Some examples of the optional console 110 may include different or additional modules than those described in conjunction with FIG. 1. Functions further described below may be distributed among components of the optional console 110 in a different manner than is described here.

In some examples, the optional console 110 may include a processor and a non-transitory computer-readable storage medium storing instructions executable by the processor. The processor may include multiple processing units executing instructions in parallel. The non-transitory computer-readable storage medium may be any memory, such as a hard disk drive, a removable memory, or a solid-state drive (e.g., flash memory or dynamic random access memory (DRAM)). In some examples, the modules of the optional console 110 described in conjunction with FIG. 1 may be encoded as instructions in the non-transitory computer-readable storage medium that, when executed by the processor, cause the processor to perform the functions further described below. It should be appreciated that the optional console 110 may or may not be needed or the optional console 110 may be integrated with or separate from the near-eye display 120.

In some examples, the application store 112 may store one or more applications for execution by the optional console 110. An application may include a group of instructions that, when executed by a processor, generates content for presentation to the user. Examples of the applications may include gaming applications, conferencing applications, video playback application, or other suitable applications.

In some examples, the headset tracking module 114 may track movements of the near-eye display 120 using slow calibration information from the external imaging device 150. For example, the headset tracking module 114 may determine positions of a reference point of the near-eye display 120 using observed locators from the slow calibration information and a model of the near-eye display 120. Additionally, in some examples, the headset tracking module 114 may use portions of the fast calibration information, the slow calibration information, or any combination thereof, to predict a future location of the near-eye display 120. In some examples, the headset tracking module 114 may provide the estimated or predicted future position of the near-eye display 120 to the virtual reality engine 116.

In some examples, the virtual reality engine 116 may execute applications within the artificial reality system environment 100 and receive position information of the near-eye display 120, acceleration information of the near-eye display 120, velocity information of the near-eye display 120, predicted future positions of the near-eye display 120, or any combination thereof from the headset tracking module 114. In some examples, the virtual reality engine 116 may also receive estimated eye position and orientation information from the eye-tracking module 118. Based on the received information, the virtual reality engine 116 may determine content to provide to the near-eye display 120 for presentation to the user.

In some examples, the eye-tracking module 118 may receive eye-tracking data from the eye-tracking unit 130 and determine the position of the user's eye based on the eye tracking data. In some examples, the position of the eye may include an eye's orientation, location, or both relative to the near-eye display 120 or any element thereof. So, in these examples, because the eye's axes of rotation change as a function of the eye's location in its socket, determining the eye's location in its socket may allow the eye-tracking module 118 to more accurately determine the eye's orientation.

In some examples, a location of a projector of a display system may be adjusted to enable any number of design modifications. For example, in some instances, a projector may be located in front of a viewer's eye (i.e., “front-mounted” placement). In a front-mounted placement, in some examples, a projector of a display system may be located away from a user's eyes (i.e., “world-side”). In some examples, a head-mounted display (HMD) device may utilize a front-mounted placement to propagate light towards a user's eye(s) to project an image.

FIG. 2 illustrates a perspective view of a near-eye display in the form of a head-mounted display (HMD) device 200, according to an example. In some examples, the HMD device 200 may be a part of a virtual reality (VR) system, an augmented reality (AR) system, a mixed reality (MR) system, another system that uses displays or wearables, or any combination thereof. In some examples, the HMD device 200 may include a body 220 and a head strap 230. FIG. 2 shows a bottom side 223, a front side 225, and a left side 227 of the body 220 in the perspective view. In some examples, the head strap 230 may have an adjustable or extendible length. In particular, in some examples, there may be a sufficient space between the body 220 and the head strap 230 of the HMD device 200 for allowing a user to mount the HMD device 200 onto the user's head. For example, the length of the head strap 230 may be adjustable to accommodate a range of user head sizes. In some examples, the HMD device 200 may include additional, fewer, and/or different components.

In some examples, the HMD device 200 may present, to a user, media or other digital content including virtual and/or augmented views of a physical, real-world environment with computer-generated elements. Examples of the media or digital content presented by the HMD device 200 may include images (e.g., two-dimensional (2D) or three-dimensional (3D) images), videos (e.g., 2D or 3D videos), audio, or any combination thereof. In some examples, the images and videos may be presented to each eye of a user by one or more display assemblies (not shown in FIG. 2) enclosed in the body 220 of the HMD device 200.

In some examples, the HMD device 200 may include various sensors (not shown), such as depth sensors, motion sensors, position sensors, and/or eye tracking sensors. Some of these sensors may use any number of structured or unstructured light patterns for sensing purposes. In some examples, the HMD device 200 may include an input/output interface 140 for communicating with a console 110, as described with respect to FIG. 1. In some examples, the HMD device 200 may include a virtual reality engine (not shown), but similar to the virtual reality engine 116 described with respect to FIG. 1, that may execute applications within the HMD device 200 and receive depth information, position information, acceleration information, velocity information, predicted future positions, or any combination thereof of the HMD device 200 from the various sensors.

In some examples, the information received by the virtual reality engine 116 may be used for producing a signal (e.g., display instructions) to the one or more display assemblies. In some examples, the HMD device 200 may include locators (not shown), but similar to the virtual locators 126 described in FIG. 1, which may be located in fixed positions on the body 220 of the HMD device 200 relative to one another and relative to a reference point. Each of the locators may emit light that is detectable by an external imaging device. This may be useful for the purposes of head tracking or other movement/orientation. It should be appreciated that other elements or components may also be used in addition or in lieu of such locators.

It should be appreciated that in some examples, a projector mounted in a display system may be placed near and/or closer to a user's eye (i.e., “eye-side”). In some examples, and as discussed herein, a projector for a display system shaped liked eyeglasses may be mounted or positioned in a temple arm (i.e., a top far corner of a lens side) of the eyeglasses. It should be appreciated that, in some instances, utilizing a back-mounted projector placement may help to reduce size or bulkiness of any required housing required for a display system, which may also result in a significant improvement in user experience for a user.

FIG. 3 is a perspective view of a near-eye display 300 in the form of a pair of glasses (or other similar eyewear), according to an example. In some examples, the near-eye display 300 may be a specific example of near-eye display 120 of FIG. 1, and may be to operate as a virtual reality display, an augmented reality display, and/or a mixed reality display.

In some examples, the near-eye display 300 may include a frame 305 and a display 310. In some examples, the display 310 may be to present media or other content to a user. In some examples, the display 310 may include display electronics and/or display optics, similar to components described with respect to FIGS. 1-2. For example, as described above with respect to the near-eye display 120 of FIG. 1, the display 310 may include a liquid crystal display (LCD) display panel, a light-emitting diode (LED) display panel, or an optical display panel (e.g., a waveguide display assembly). In some examples, the display 310 may also include any number of optical components, such as waveguides, gratings, lenses, mirrors, etc.

In some examples, the near-eye display 300 may further include various sensors 350a, 350b, 350c, 350d, and 350e on or within a frame 305. In some examples, the various sensors 350a-350e may include any number of depth sensors, motion sensors, position sensors, inertial sensors, and/or ambient light sensors, as shown. In some examples, the various sensors 350a-350e may include any number of image sensors to generate image data representing different fields of views in one or more different directions. In some examples, the various sensors 350a-350e may be used as input devices to control or influence the displayed content of the near-eye display 300, and/or to provide an interactive virtual reality (VR), augmented reality (AR), and/or mixed reality (MR) experience to a user of the near-eye display 300. In some examples, the various sensors 350a-350e may also be used for stereoscopic imaging or other similar application.

In some examples, the near-eye display 300 may further include one or more illuminators 330 to project light into a physical environment. The projected light may be associated with different frequency bands (e.g., visible light, infra-red light, ultra-violet light, etc.), and may serve various purposes. In some examples, the one or more illuminator(s) 330 may be used as locators, such as the one or more locators 126 described above with respect to FIGS. 1-2.

In some examples, the near-eye display 300 may also include a camera 340 or other image capture unit. The camera 340, for instance, may capture images of the physical environment in the field of view. In some instances, the captured images may be processed, for example, by a virtual reality engine (e.g., the virtual reality engine 116 of FIG. 1) to add virtual objects to the captured images or modify physical objects in the captured images, and the processed images may be displayed to the user by the display 310 for augmented reality (AR) and/or mixed reality (MR) applications.

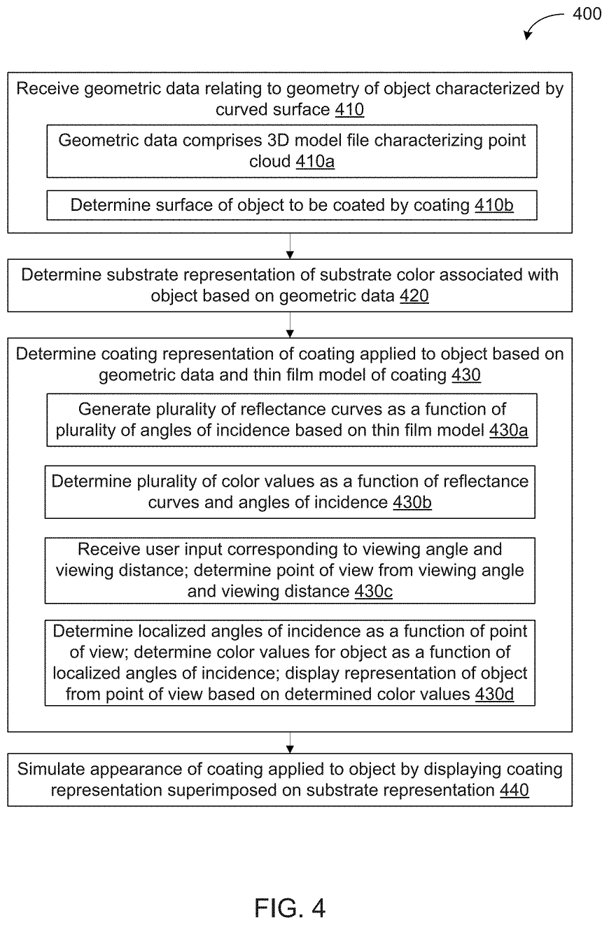

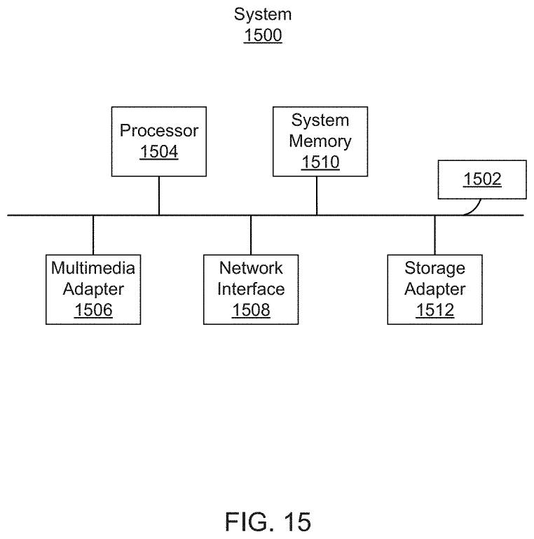

FIG. 4 is a flow diagram illustrating an example method 400 for simulating the color appearance of a coating on a three-dimensional object, according to various examples. In various examples, the method 400 is performed by a device (e.g., the computer system 1500 of FIG. 15). In some examples, the method 400 is performed by processing logic, including hardware, firmware, software, or a combination thereof. The method 400 may be performed by a processor executing code stored in a non-transitory computer-readable medium (e.g., a memory). Briefly, in various examples, the method 400 may include receiving geometric data relating to a geometry of an object characterized by a curved surface. A substrate representation of a substrate color associated with the object may be determined based on the geometric data. A coating representation of a coating applied to the object may be determined based on the geometric data and a thin film model of the coating. An appearance of the coating applied to the object may be simulated by displaying the coating representation superimposed on the substrate representation.

In various examples, as represented by block 410, the method 400 may include receiving geometric data relating to a geometry of an object characterized by a curved surface. For example, the geometric data may be sourced from a computer-aided design (CAD) program. In some examples, as represented by block 410a, the geometric data may include a three-dimensional model file characterizing a point cloud. An example of a three-dimensional model file that may characterize a point cloud is a stereolithography (STL) file, which may have the extension stl. Point cloud data may be extracted from the stereolithography file.

In some examples, as represented by block 410b, the method 400 may include determining a surface of the object to be coated by the coating. For example, all relevant surfaces to be coated by an anti-reflective film may be identified. Other surfaces may be deleted, e.g., omitted from further consideration in determining reflection curves as described herein. For example, surfaces that are not user-facing or world-facing are not seen on the product and may be omitted from consideration in determining reflection curves. Omitting these other surfaces may conserve computational resources. In some examples, respective center points of each identified surface may be identified. The identified center points may be used in calculating angles of incidence as described herein.

In various examples, as represented by block 420, the method 400 may include determining a substrate representation of a substrate color associated with the object based on the geometric data. The substrate representation may represent a color of an ink or a base coat that is applied to the object, e.g., a coat of paint or primer. In some examples, the substrate representation may represent a color of a material from which the object is formed, e.g., plastic or metal.

In some examples, the substrate representation is displayed. In some examples, color values associated with the substrate representation are determined, but the substrate representation is not displayed. L*a*b* color values in the CIELAB color space or spectral reflectance curves may be used to adjust for substrate colors in the substrate representation. In the CIELAB color space, the lightness value, L*, defines black at 0 and white at 100. The a* axis represents the green-red opponent colors, with negative values of a* toward green and positive values of a* toward red. The b* axis represents the blue-yellow opponent colors, with negative values of b* toward blue and positive values of b* toward yellow. The a* and b* axes are theoretically unbounded, but computer implementations of the CIELAB color space may impose bounds on the a* and b* axes, e.g., to facilitate representation of a* and b* values. For example, a* and b* values may be limited to the range of −128 to +127. Known or measured L*a*b* values for substrate or ink colors may be used as an input for the simulation. If L*a*b* values are not known, they may be calculated within the simulation software via the reflectance curves of the substrate or ink. This may provide the base color over which a color of a coating (e.g., an anti-reflective coating) may be mapped.

Referring again to FIG. 4, as represented by block 430, the method 400 may include determining a coating representation of a coating applied to the object based on the geometric data and a thin film model of the coating. A thin film model represents the coating as a thin layer distributed uniformly over the substrate (e.g., the object) and can be used to predict reflectance and color values based on reflectivity properties of the coating. A variety of coating types may be simulated. For example, known anti-reflective (AR) coating designs and materials may be applied to a substrate, and their effects may be simulated. As another example, the color effects of other types of coatings, such as glazes, may be simulated. The subject matter described herein may be generally applicable to simulating color effects of coatings that exhibit color dependency on angle of incidence, e.g., coatings that may be characterized by reflectance as a function of wavelength and/or angle of incidence.

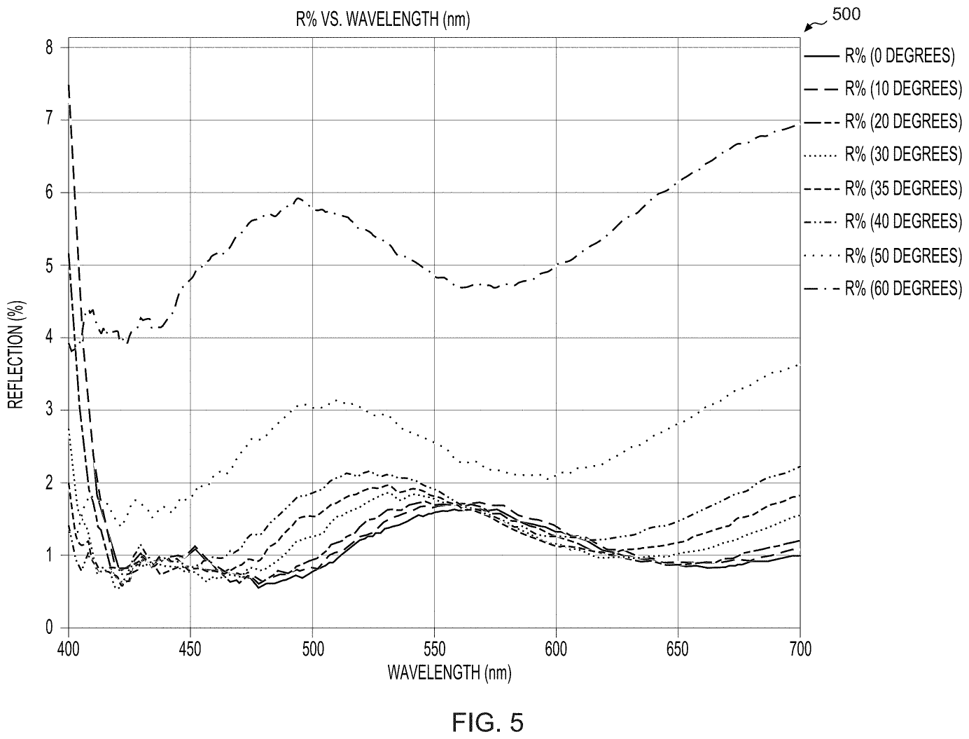

In some examples, as represented by block 430a, the method 400 may include generating a plurality of reflectance curves as a function of a plurality of angles of incidence based on the thin film model. For example, reflectance curves may be received from thin film design software from a number of angles of incidence (e.g., 0, 35, and 70 degrees). FIG. 5 illustrates a diagram of a set 500 of reflectance curves, according to some examples. As represented in FIG. 5, the set 500 of reflectance curves plots reflectance (in percentage) as a function of wavelength (in nanometers) for a range of angles of incidence between 0 degrees and 60 degrees.

In some examples, reflectance values may be interpolated (e.g., using linear interpolation) for angles of incidence for which reflectance curves are not available. For example, reflectance curves may be received from the thin film design software for angles of incidence at 10 degree increments between 0 degrees and 70 degrees. Interpolation may be used to determine reflectance curves for the remaining angles of incidence at 1 degree increments between 1 degree and 69 degrees.

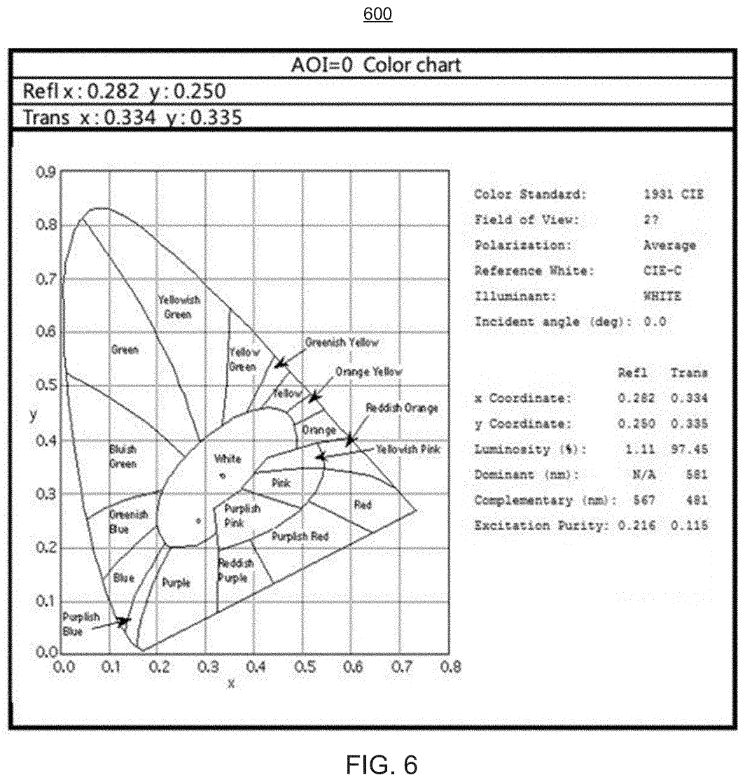

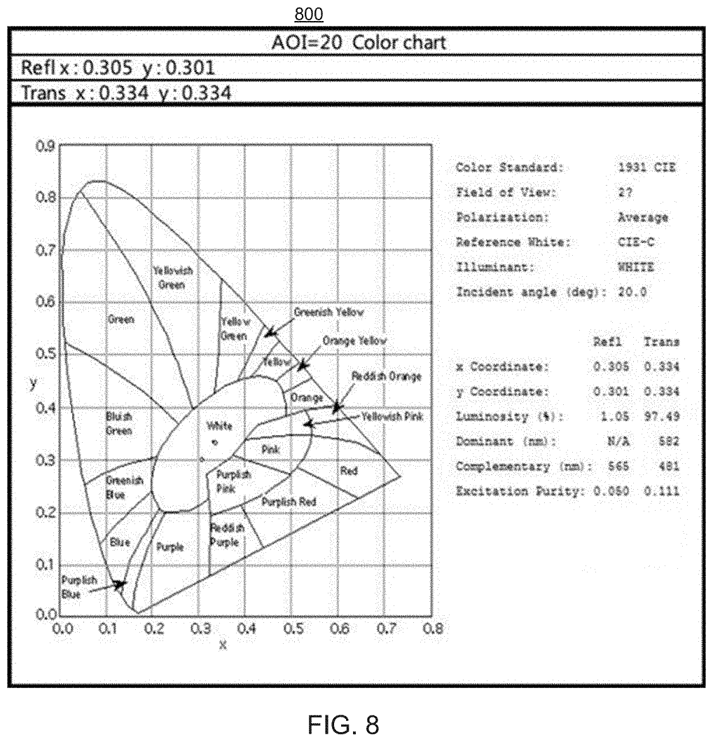

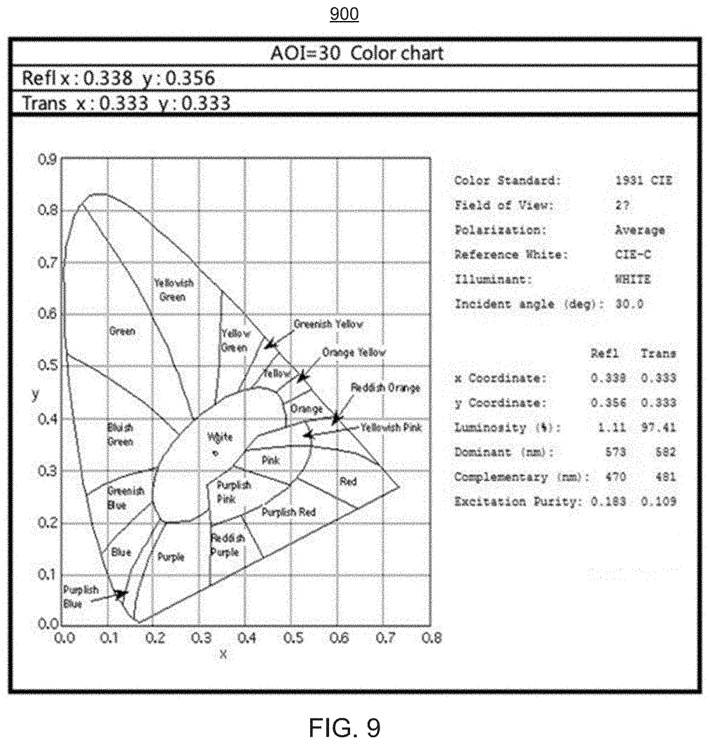

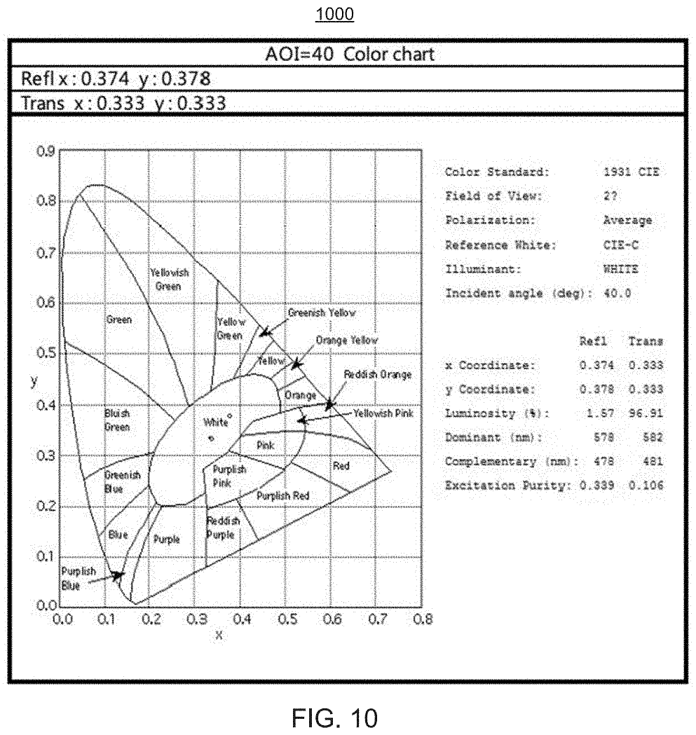

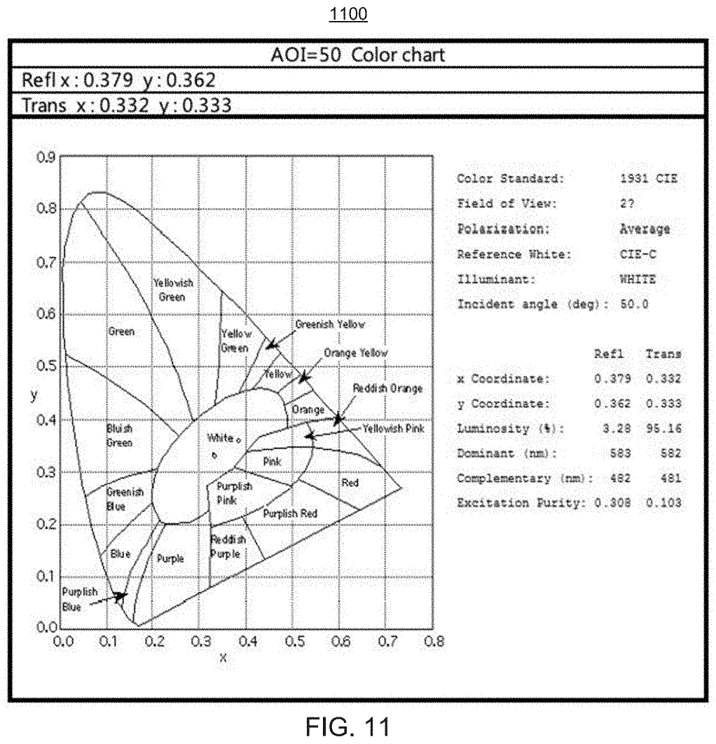

Referring again to FIG. 4, as represented by block 430b, the method 400 may include determining a plurality of color values as a function of the reflectance curves and the angles of incidence. For example, simulation software may convert the reflectance values as a function of angles of incidence to color values as a function of angles of incidence. Color values may be expressed as RGB values. In some examples, color values may be expressed as L*a*b* values. FIGS. 6-11 illustrate example color charts 600, 700, 800, 900, 1000, 1100 for angles of incidence of 0, 10, 20, 30, 40, and 50 degrees, respectively. In the color charts shown in FIGS. 6-11, corresponding L*a*b* color values are shown fora simulated object having a violet substrate (e.g., color standard 1931 CIE) and a uniformly applied anti-reflective coating. The color values may assume a white illuminant and average polarization.

Referring again to FIG. 4, as represented by block 430c, the method 400 may include receiving a user input corresponding to a viewing angle and a viewing distance. For example, the user may position a cursor to indicate the viewing angle and/or the viewing distance. As another example, the user may enter values in input fields to indicate the viewing angle and/or the viewing distance. As also represented by block 430c, a point of view may be determined from the viewing angle and the viewing distance.

In some examples, as represented by block 430d, the method 400 may include determining localized angles of incidence as a function of the point of view. As described herein in connection with block 410b, the method 400 may include determining a surface or surfaces of the object to be coated by the coating. For example, all relevant surfaces to be coated by an anti-reflective film may be identified. In some examples, respective localized angles of incidence may be calculated for each such surface based on the geometric data (e.g., the stereolithography (STL) file). An angle of incidence for a surface may be determined with respect to the center point of the surface as determined in connection with block 410b. Curved surfaces may have multiple localized angles of incidence. For example, a curved surface may have a localized angle of incidence for each point in the point cloud represented by the geometric data. As another example, the number of localized angles of incidence associated with a curved surface may depend on the granularity with which the angles of incidence are sampled.

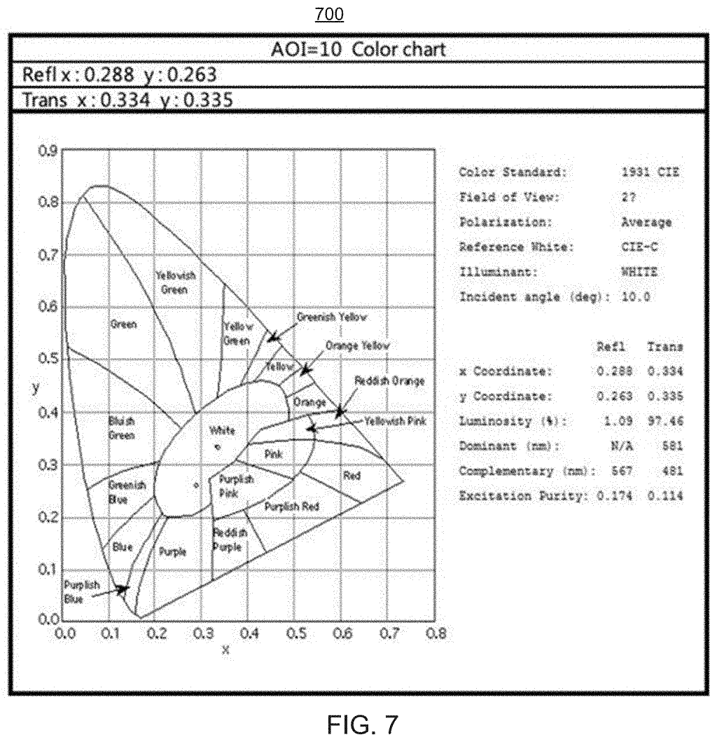

As also represented by block 430d, color values may be determined for the object as a function of the localized angles of incidence. For example, for a curved surface having multiple localized angles of incidence, reflectance values may be determined as a function of the localized angles of incidence. The reflectance values may be converted to color values, for example, using color charts similar to the color charts illustrated in FIGS. 7-12. As also represented by block 430d, a representation of the object may be displayed from the point of view determined based on the user input. This displayed coating representation may be based on the determined color values. The displayed coating representation may represent the color of the coating itself. In some examples, color values associated with the coating representation are determined, but the coating representation is not displayed.

Referring again to FIG. 4, as represented by block 440, the method 400 may include simulating an appearance of the coating applied to the object by displaying the coating representation superimposed on the substrate representation. FIGS. 18-20 illustrate diagrams of various representations of coatings applied on substrates as viewed from various angles, according to some examples. In some examples, the transparency of the coating representation may be adjusted when the coating representation is superimposed on the substrate representation. Adjusting the transparency of the coating representation may promote visibility of the substrate representation when the coating representation is superimposed on the substrate representation.

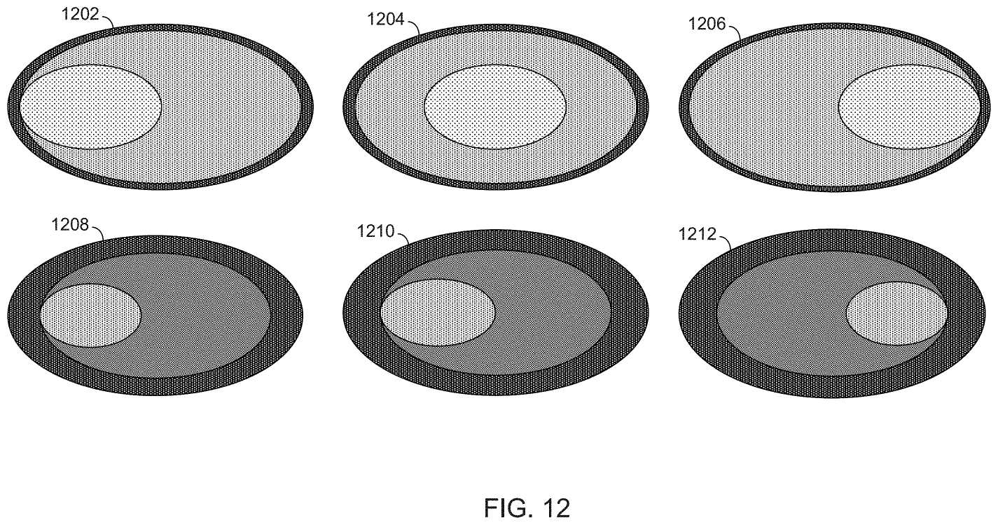

In some examples, simulating the color appearance of coatings on three-dimensional objects as described herein may facilitate a product design process. For example, a product design process may involve simulation of multiple instances of an object. Each instance has a different coating design, e.g., a different anti-reflective (AR) coating formulation. In some examples, Monte Carlo simulations of coating designs may be performed to visualize the color appearance of limit samples via simulation. Performing Monte Carlo simulations may reduce or avoid the need to produce physical samples and components associated with determining limit samples. As represented by FIGS. 12-14, a variety of viewing angles and distances may be simulated. For example, FIG. 12 illustrates a diagram of an anti-reflective coating as viewed from a left-shifted view 1202, a front view 1204, and a right-shifted view 1206. FIG. 12 also illustrates an object including a substrate and the anti-reflective coating as viewed from a left-shifted view 1208, a front view 1210, and a right-shifted view 1212.

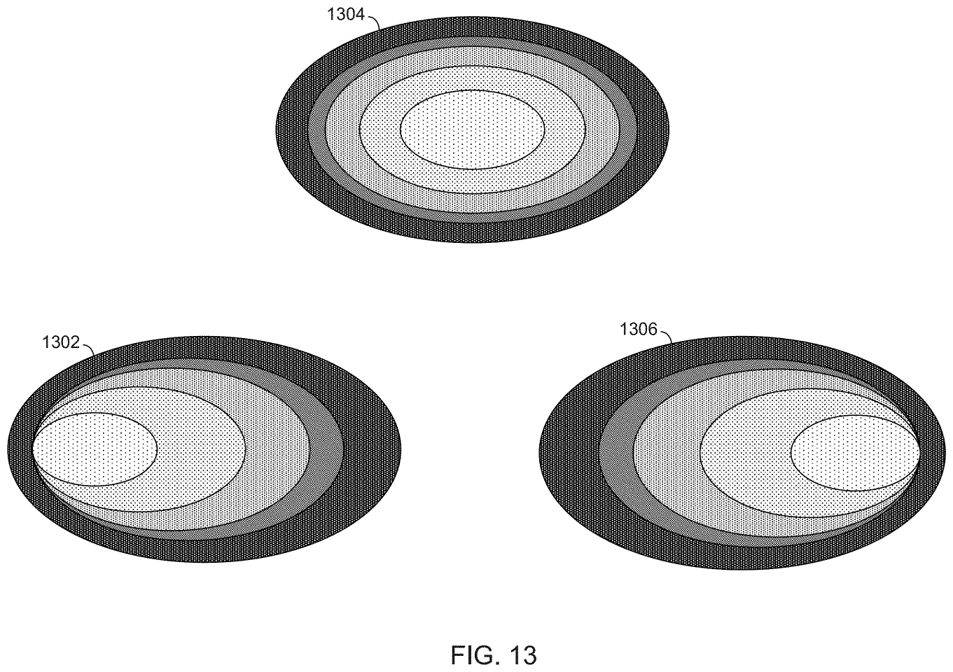

As represented by FIG. 13, a variety of coatings may be simulated. FIG. 13 illustrates a diagram of a simulation of a coating characterized by an unstable color shift that is dependent on the angle of incidence. The coating is illustrated in a left-shifted view 1302, a front view 1304, and a right-shifted view 1306. Each view includes multiple colors, such as blue and red.

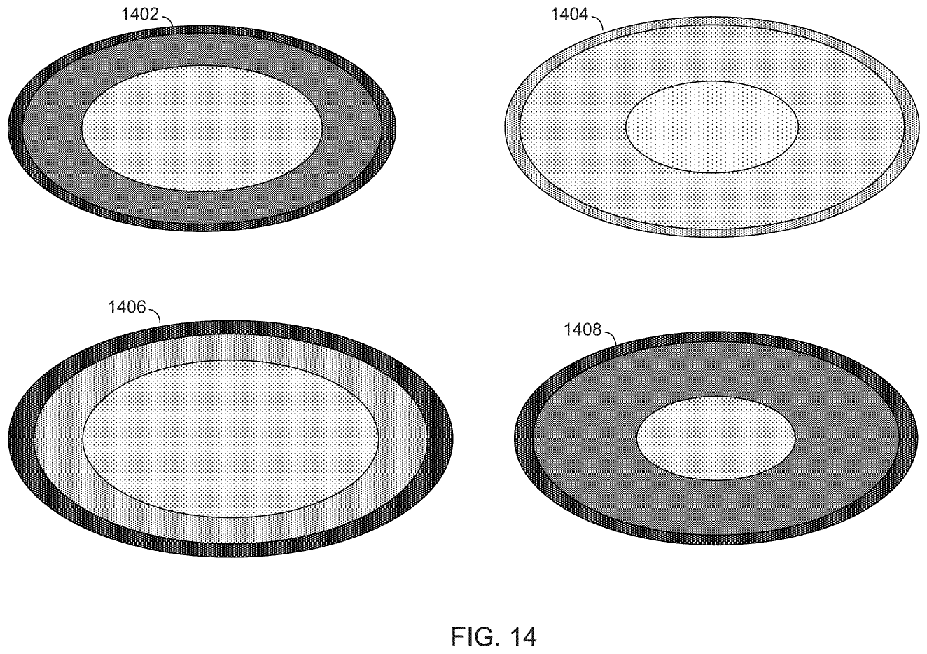

As represented by FIG. 14, a variety of substrate colors may be simulated. FIG. 14 illustrates a diagram of a simulation of an anti-reflective (AR) coating applied to four different substrates 1402, 1404, 1406, 1408. The simulated coating is constant between the substrates 1402, 1404, 1406, 1408.

FIG. 15 illustrates a block diagram of a computer system 1500 for simulating the color appearance of coatings on three-dimensional objects, according to an example. The computer system 1500 may include, among other things, an interconnect 1502, a processor 1504, a multimedia adapter 1506, a network interface 1508, a system memory 1510, and a storage adapter 1512.

The interconnect 1502 may interconnect various subsystems, elements, and/or components of the computer system 1500. As shown, the interconnect 1502 may be an abstraction that may represent any one or more separate physical buses, point-to-point connections, or both, connected by appropriate bridges, adapters, or controllers. In some examples, the interconnect 1502 may include a system bus, a peripheral component interconnect (PCI) bus or PCI-Express bus, a HyperTransport or industry standard architecture (ISA)) bus, a small computer system interface (SCSI) bus, a universal serial bus (USB), IIC (I2C) bus, or an Institute of Electrical and Electronics Engineers (IEEE) standard 1394 bus, or “firewire,” or other similar interconnection element.

In some examples, the interconnect 1502 may allow data communication between the processor 1504 and system memory 1510, which may include read-only memory (ROM) or flash memory (neither shown), and random access memory (RAM) (not shown). It should be appreciated that the RAM may be the main memory into which an operating system and various application programs may be loaded. The ROM or flash memory may include, among other code, the Basic Input-Output system (BIOS) that controls basic hardware operation, such as the interaction with one or more peripheral components.

The processor 1504 may be the central processing unit (CPU) of the computing device and may control overall operation of the computing device. In some examples, the processor 1504 may accomplish this by executing software or firmware stored in system memory 1510 or other data via the storage adapter 1512. The processor 1504 may be, or may include, one or more programmable general-purpose or special-purpose microprocessors, digital signal processors (DSPs), programmable controllers, application specific integrated circuits (ASICs), programmable logic device (PLDs), trust platform modules (TPMs), field-programmable gate arrays (FPGAs), other processing circuits, or a combination of these and other devices.

The multimedia adapter 1506 may connect to various multimedia elements or peripherals. These may include devices associated with visual (e.g., video card or display), audio (e.g., sound card or speakers), and/or various input/output interfaces (e.g., mouse, keyboard, touchscreen).

The network interface 1502 may provide the computing device with an ability to communicate with a variety of remote devices over a network and may include, for example, an Ethernet adapter, a Fibre Channel adapter, and/or another wired- or wireless-enabled adapter. The network interface 1502 may provide a direct or indirect connection from one network element to another, and facilitate communication and between various network elements.

The storage adapter 1512 may connect to a standard computer-readable medium for storage and/or retrieval of information, such as a fixed disk drive (internal or external).

Many other devices, components, elements, or subsystems (not shown) may be connected in a similar manner to the interconnect 1502 or via a network. Conversely, all of the devices shown in FIG. 15 need not be present to practice the subject matter described in the present disclosure. The devices and subsystems can be interconnected in different ways from that shown in FIG. 15. Code to implement the techniques for simulating the color appearance of coatings on three-dimensional objects described in the present disclosure may be stored in nontransitory computer-readable storage media such as one or more of system memory 1510 or other storage. Code to implement the techniques for simulating the color appearance of coatings on three-dimensional objects described in the present disclosure may also be received via one or more interfaces and stored in memory. The operating system provided on system 1500 may be MS-DOS, MS-WINDOWS, OS/2, OS X, IOS, ANDROID, UNIX, Linux, or another operating system.

In the foregoing description, various examples are described, including devices, systems, methods, and the like. For the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples.

The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example’ is not necessarily to be construed as preferred or advantageous over other embodiments or designs.

Although the methods and systems as described herein may be directed mainly to digital content, such as videos or interactive media, it should be appreciated that the methods and systems as described herein may be used for other types of content or scenarios as well. Other applications or uses of the methods and systems as described herein may also include social networking, marketing, content-based recommendation engines, and/or other types of knowledge or data-driven systems.

1. A system, comprising:
a processor; and
a memory storing processor-executable instructions that, when executed by the processor, cause the processor to:
receive geometric data relating to a geometry of an object characterized by a curved surface;
determine a substrate representation of a substrate color associated with the object based on the geometric data;
determine a coating representation of a coating applied to the object based on the geometric data and a thin film model of the coating; and
simulate an appearance of the coating applied to the object by displaying the coating representation superimposed on the substrate representation.

2. The system of claim 1, wherein the geometric data comprises a three-dimensional model file characterizing a point cloud.

3. The system of claim 1, wherein the processor-executable instructions further cause the processor to determine a surface of the object to be coated by the coating.

4. The system of claim 1, wherein the processor-executable instructions further cause the processor to generate a plurality of reflectance curves as a function of a plurality of angles of incidence based on the thin film model.

5. The system of claim 4, wherein the processor-executable instructions further cause the processor to determine a plurality of color values as a function of the reflectance curves and the angles of incidence.

6. The system of claim 4, wherein the processor-executable instructions further cause the processor to:
receive a user input corresponding to a viewing angle and a viewing distance; and
determine a point of view from the viewing angle and the viewing distance.

7. The system of claim 6, wherein the processor-executable instructions further cause the processor to:
determine localized angles of incidence as a function of the point of view;
determine color values for the object as a function of the localized angles of incidence; and
display a representation of the object from the point of view based on the determined color values.

8. A method, comprising:
receiving geometric data relating to a geometry of an object characterized by a curved surface;
determining a substrate representation of a substrate color associated with the object based on the geometric data;
determining a coating representation of a coating applied to the object based on the geometric data and a thin film model of the coating; and
simulating an appearance of the coating applied to the object by displaying the coating representation superimposed on the substrate representation.

9. The method of claim 8, wherein the geometric data comprises a three-dimensional model file characterizing a point cloud.

10. The method of claim 8, further comprising determining a surface of the object to be coated by the coating.

11. The method of claim 8, further comprising generating a plurality of reflectance curves as a function of a plurality of angles of incidence based on the thin film model.

12. The method of claim 11, further comprising determining a plurality of color values as a function of the reflectance curves and the angles of incidence.

13. The method of claim 11, further comprising:
receiving a user input corresponding to a viewing angle and a viewing distance; and
determining a point of view from the viewing angle and the viewing distance.

14. The method of claim 13, further comprising:
determining localized angles of incidence as a function of the point of view;
determining color values for the object as a function of the localized angles of incidence; and
displaying a representation of the object from the point of view based on the determined color values.

15. A non-transitory computer readable storage medium comprising an executable that, when executed, instructs a processor to:
receive geometric data relating to a geometry of an object characterized by a curved surface;
determine a substrate representation of a substrate color associated with the object based on the geometric data;
determine a coating representation of a coating applied to the object based on the geometric data and a thin film model of the coating; and
simulate an appearance of the coating applied to the object by displaying the coating representation superimposed on the substrate representation.

16. The computer readable storage medium of claim 15, wherein the geometric data comprises a three-dimensional model file characterizing a point cloud.

17. The computer readable storage medium of claim 15, wherein the executable further causes the processor to determine a surface of the object to be coated by the coating.

18. The computer readable storage medium of claim 15, wherein the executable further causes the processor to:
generate a plurality of reflectance curves as a function of a plurality of angles of incidence based on the thin film model; and
determine a plurality of color values as a function of the reflectance curves and the angles of incidence.

19. The computer readable storage medium of claim 18, wherein the executable further causes the processor to:
receive a user input corresponding to a viewing angle and a viewing distance; and
determine a point of view from the viewing angle and the viewing distance.

20. The computer readable storage medium of claim 19, wherein the executable further causes the processor to:
determine localized angles of incidence as a function of the point of view;
determine color values for the object as a function of the localized angles of incidence; and
display a representation of the object from the point of view based on the determined color values.
